(19) United States
(12) Patent Application Publication
(10) Pub. No.: US 2023/0042257 A1
(43) Pub. Date: Feb. 9, 2023

(54) CAPACITIVE DETECTION DEVICE COMPRISING A MODULE FOR POLARIZATION BY INDUCTION

(71) Applicant: FOGALE SENSORS, Nîmes (FR)

(72) Inventors: Christian NEEL, Nîmes (FR); Didier ROZIERE, Nîmes (FR); Stéphane DAVID-GRIGNOT, Prades le Lez (FR)

(21) Appl. No.: 17/758,420

(22) PCT Filed: Dec. 29, 2020
(86) PCT No.: PCT/EP2020/087949

§ 371 Date: Jul. 6, 2022

(30) Foreign Application Priority Data
Jan. 8, 2020 (FR) FR2000113

(51) Int. Cl. G01D 5/24; G01R 15/18; G06F 3/044

(52) U.S. Cl. CPC G01D 5/24; G01R 15/18; G06F 3/044; B25J 19/02

(57) ABSTRACT

A device for capacitive detection of an object (O), including at least one biasing module configured to bias at least one measurement electrode at an alternating electric potential (Vg), referred to as work potential, different from a ground potential (M); and measurement electronics; at least one biasing module including at least one toroidal element, referred to as excitation element, with a central opening designed to induce, in at least one electrical conductor which passes therethrough and which is in electrical connection with at least one measurement electrode, an alternating potential difference equal to the alternating electrical work potential (Vg), between an input and an output of the at least one toroidal element. An apparatus using such a capacitive detection device is also included.

The present invention relates to a capacitive detection device. It also relates to an appliance utilizing such a capacitive detection device.

The field of the invention is the field of interfaces for capacitive detection of objects, and in particular detection interfaces for the field of robotics.

### STATE OF THE ART

A device for capacitive detection of objects comprises measurement electrodes and measurement electronics, which, according to a well-known technology, are arranged to measure an electrical signal relative to the object-electrode capacitance, denoted Cₒₑ in the present application, seen by one or more measurement electrodes. To this end, the measurement electrode or electrodes must be polarized at an alternating potential different from the electrical potential of the object to be detected. This therefore requires an alternating electrical potential to be applied to each measurement electrode used.

However, when an appliance is equipped with the capacitive detection device, it is sometimes difficult to apply the polarization potential to each measurement electrode without modifying the architecture of said appliance, for example by adding electric wires, by moving certain wires of the appliance, or also by adding trim elements to the appliance to bear the electrodes. This is all the more problematic when it is desired to directly use parts of the appliance such as the measurement electrode.

In addition, as the appliance is generally electrically referenced to a potential different from that of the measurement electrodes, there can be electrical conductors or elements of the appliance which are located in proximity to the measurement electrodes, which are polarized at a different electrical potential and which can therefore disrupt the capacitive detection by creating parasitic capacitances with the measurement electrodes, preventing or disrupting the detection of an object. These disruptions can be limited or removed, in a known manner, by inserting elements, called guard elements, polarized at the same potential as the measurement electrodes at least at the working frequency of the capacitive detection, between these measurement electrodes and the elements of the appliance polarized at other potentials. However, this is not always possible, or requires a more significant modification of the appliance.

Thus, the addition of a capacitive detection device to an appliance can prove difficult, costly and time-consuming, in particular when it is carried out retrospectively on existing appliances.

An aim of the present invention is to overcome at least one of the above-mentioned drawbacks.

Another aim of the present invention is to propose a capacitive detection device that is easier, less costly and less expensive to implement on an appliance, and in particular an existing appliance.

Another aim of the present invention is to propose such a capacitive detection device allowing a better rejection of parasitic capacitances.

### DISCLOSURE OF THE INVENTION

The invention makes it possible to achieve at least one of these aims with a device for capacitive detection of an object, comprising:
at least one polarization module configured to polarize at least one measurement electrode at an alternating electrical potential, called working potential, different from a ground potential; and
measurement electronics configured to measure a signal relating to a capacitance, called object-electrode capacitance, seen by said at least one measurement electrode, at a working frequency;
   characterized in that at least one polarization module comprises at least one toroidal element, called excitation toroidal element, with a central opening:
provided to be placed around an electrical conductor electrically connected to said at least one measurement electrode, through the central opening, and
comprising at least one electrical winding, supplied by an alternating electrical signal, arranged to generate a circular magnetic field in said excitation toroidal element and an axial magnetic field vector potential in said central opening;
   so as to induce, in said electrical conductor, an alternating potential difference equal to said working alternating electrical potential, between an input and an output of said at least one toroidal element.

The electrical winding can in particular be supplied by an alternating electrical voltage.

Thus, in the capacitive detection device according to the invention, the polarization of the at least one measurement electrode is produced by induction, by placing at least one excitation toroidal element around a conductor which is electrically connected to the at least one measurement electrode. The excitation toroidal element adds a potential difference corresponding to the working alternating potential, denoted V_{g} below, to the electrical conductor passing through said excitation toroidal element, on the downstream portion of said conductor, i.e. on the portion of the conductor located on the side of the at least one measurement electrode. This principle will be described in more detail with reference to FIG. 1.

As a result, in the device according to the invention, the polarization of the at least one measurement electrode does not require the creation of an electrical contact, or the utilization of a track or an electric wire to polarize each measurement electrode. Thus, it is easier, less costly or less time-consuming to equip an appliance with a capacitive detection device according to the invention.

In addition, the at least one excitation toroidal element can be used to polarize, in addition to the at least one measurement electrode, any electrically conductive part of the appliance and which could optionally disrupt the capacitive detection, and potentially the whole appliance, with very little, if any, modification of said appliance, by positioning the at least one excitation toroidal element around a suitable portion of said appliance. Thus, the invention makes it possible to equip an appliance with a capacitive detection device while allowing a better rejection of parasitic capacitances.

Moreover, the at least one excitation toroidal element can be used to polarize any electrically conductive part of the appliance at the working potential V_{g}. As a result, each electrically conductive part of an appliance can potentially be used as a measurement electrode, which makes it possible to limit, or even to avoid, the addition of additional measurement electrodes on an appliance to equip it with a capacitive detection functionality. Thus, the invention makes it possible to equip an appliance with a capacitive detection device in a simpler, less costly and quicker manner.

In the present document, the term “ground potential”, denoted M below, denotes a reference potential of the measurement electronics, which can be for example an electrical earth or a general ground potential. This ground potential can correspond to an earth potential or to another potential, connected or not to the earth potential.

In the present document, two alternating potentials are identical or similar, at a given frequency, when they each include an identical alternating component at this frequency; i.e. having the same amplitude and the same phase. Thus, at least one of the two identical potentials at said frequency can also include for example a direct component, and/or an alternating component having a frequency different from said given frequency.

Similarly, two alternating potentials are different at the working frequency when they do not include an alternating component that is identical at this working frequency.

It should be remembered that an electrical potential is defined with respect to a reference potential, such as for example the ground potential M. It thus corresponds to a potential difference with respect to this reference or ground potential.

The invention can be implemented with any type of electrical conductor. In particular, at least one electrical conductor electrically connected to at least one measurement electrode can be or comprise:
a track, an electric wire, a cable, a data bus, or
a part or a portion of an appliance equipped with the detection device according to the invention, such as a trim element, a framework element, a segment in the case of a robot or a robotized arm, a cable or a bundle of cables, etc., or
a portion or all of the body of an appliance equipped with the detection device according to the invention, for example a robot segment or all of the robot in the case of a robot or a robotized arm.

Moreover, according to the invention, the electrical conductor can be electrically connected to the at least one measurement electrode in any way making it possible to transmit the potential induced by the polarization module to this or these electrodes. This electrical connection can be for example direct, by contact, or produced through or via components or electronic circuits.

In the present document, for a polarization module:
by “input of the polarization module” or “input of the at least one toroidal element” is meant the end of the central opening of said at least one toroidal element located on the opposite side to the at least one measurement electrode, and
by “output of the polarization module” or “output of the at least one toroidal element” is meant the end of the central opening of said at least one toroidal element located on the side of the at least one measurement electrode;
in the direction defined by the at least one conductor connected to said at least one measurement electrode.

According to an embodiment, the polarization module can comprise several toroidal elements, each comprising at least one electrical winding supplied by an alternating voltage, so as to induce an alternating potential difference equal to the working alternating electrical potential in any conductor passing through all of said toroidal elements.

In other words, the toroidal elements of a polarization module are placed in a cascade, or in series, or aligned, along each electrical conductor which passes through all of them.

This embodiment makes it possible to generate a high working alternating electrical potential with a lower voltage source. In fact, for a total alternating potential difference ΔV, each excitation toroidal element “i” generates a portion ΔV, of said alternating electrical potential difference ΔV in each electrical conductor which passes through it so that the working alternating electrical potential corresponds to the sum ΣAVᵢ of all the alternating electrical potential differences generated by said excitation toroidal elements along each conductor which passes through all of said toroidal elements one after another.

At least one, in particular each, excitation toroidal element can have a circular, rectangular, square cross section, or any other geometric shape. Alternatively, or in addition, at least one excitation toroidal element can have a circular shape, or more generally a shape having rotational symmetry. This makes it possible in particular to generate a magnetic field vector potential with good uniformity in the central opening of said excitation toroidal element.

At least one excitation toroidal element may not comprise a core. In this case, the at least one electrical winding of said excitation toroidal element can be wound around an empty space, for example around a space filled with air.

In this case, in particular, the excitation toroidal element consists of the at least one electrical winding. In other words, the at least one electrical winding forming the excitation toroidal element has a toroid shape with a central opening. The magnetic field is then guided by the electrical winding itself.

Alternatively, at least one excitation toroidal element can comprise a core around which is wound the at least one electrical winding.

In this case, the core is toroid in shape and includes a central opening.

The core can have a cross section in the same shape as the cross-section of the at least one electrical winding, or a cross section in a different shape.

The core can have the same shape as the electrical winding or a different shape.

In particular, the core can have a circular shape, and more generally a shape having rotational symmetry.

According to an embodiment, this core can be made from a non-ferromagnetic material, and thus have a relative magnetic permeability close to 1, or for example less than 100. In this case, the at least one electrical winding of the excitation toroidal element is toroid in shape, with one or more turns, and includes a central opening. As previously, the magnetic field is then guided by the electrical winding itself.

According to an alternative, and particularly advantageous, embodiment, at least one excitation toroidal element can comprise a ferromagnetic core around which is wound the at least one electrical winding of said excitation toroidal element.

This ferromagnetic core can be made from any material having a relative magnetic permeability much greater than 1, or for example greater than 100, or 1000. It can for example be made from ferromagnetic ceramics, or ferrite. It can also be made from a ferromagnetic alloy, for example of the mu-metal or permalloy type.

In this case, the at least one electrical winding of the excitation toroidal element can have a shape that is toroid or not. In fact, the toroid-shaped core of ferromagnetic material allows, due to its high relative magnetic permeability, guiding and circular circulating in the core of the magnetic field created by the electrical winding wound around it, even if the electrical winding is not toroid in shape.

The at least one winding of at least one excitation toroidal element can comprise one or more turns.

It can also comprise, in particular when it is implemented with a ferromagnetic core, a partial turn, which passes inside the core but which does not go completely around it.

According to an embodiment, at least one excitation toroidal element can comprise a single electrical winding.

Alternatively, at least one excitation toroidal element can comprise several distinct electrical windings. This embodiment allows greater polarization homogeneity because the working alternating electrical potential is generated more homogeneously in the volume of the excitation toroidal element. This embodiment also allows greater flexibility of production of the capacitive detection device because it allows greater freedom for positioning the electrical windings.

For example, the electrical windings of an excitation toroidal element can be distributed along the excitation toroidal element at a constant angular pitch.

At least two electrical windings of an excitation toroidal element can be supplied by one and the same electrical source, or by different electrical sources.

At least two electrical windings of an excitation toroidal element can be identical. In this case said electrical windings are supplied by one and the same alternating voltage.

At least two electrical windings of an excitation toroidal element can be different. In this case said electrical windings are preferably supplied by alternating voltages having the same frequency but different amplitudes, so that each winding, taken individually, can induce one and the same potential difference in the conductors through the central opening.

According to a particularly advantageous characteristic, the polarization module can comprise, for at least one electrical winding of an excitation toroidal element, an electric power supply circuit for said winding forming, with said electrical winding, a resonant circuit tuned to the working frequency.

In other words, the or each electrical winding of at least one excitation toroidal element is supplied through a resonant circuit formed with said electrical winding. This makes it possible to reduce the electrical power used for excitation in order to generate the working alternating potential V_{g}. In fact, the use of a resonant circuit tuned to the working frequency f_{g}, makes it possible to reduce the current consumed for an electric power supply voltage, which makes it possible to reduce the power consumed.

Advantageously, the measurement electronics can be electrically referenced to the working potential.

To this end, the measurement electronics can for example be placed between the measurement electrode and the polarization module, i.e. downstream of the polarization module. In this case, the electrical lines supplying, or connected to, the measurement electronics are polarized at the working potential by the polarization module. The measurement electrode can then be polarized at the working potential via the measurement electronics.

Alternatively, particularly when they are placed upstream of the polarization module, the measurement electronics can be referenced to a potential other than the working potential, such as for example the ground potential.

The measurement electronics can be produced by any means. They can comprise at least one digital component, or at least one analogue component, or also a combination of at least one digital component and at least one analogue component. Moreover, their functions can be carried out by physical components, and/or at least partly by code implemented in a microprocessor or an FPGA.

The device according to the invention can comprise an induction sensor, connected to the measurement electronics, configured to provide said measurement electronics with an electrical signal as a function of the electrode-object capacitance, denoted Cₒₑ, seen by at least one measurement electrode.

The induction sensor can comprise at least one toroidal element, called receiving toroidal element, comprising a central opening:
provided to be placed around an electrical conductor electrically connected to said at least one measurement electrode, and
comprising at least one electrical winding in which said electrical signal is induced.

This induction sensor is sensitive to the current flowing in the electrical conductor and resulting from the capacitive coupling between the measurement electrode and the object, causing the electrode-object capacitance Cₒₑ. It thus provides the measurement electronics with an electrical signal depending on this current.

More generally, the induction sensor is sensitive to all of the currents flowing in the electrical conductors passing through its central opening and resulting from the capacitive couplings between elements (acting as capacitive electrodes) electrically connected to these conductors and the surroundings.

It should be noted that the induction sensor is sensitive to all of the currents flowing in the electrical conductors which pass through its central opening. Thus, generally, when the induction sensor is placed around all of the conductors of an electrical circuit, the currents other than those resulting from the capacitive couplings, such as for example the electric power supply or electrical signal currents, flow equally in the two directions in the induction sensor and their contributions therefore cancel each other out.

Generally, the induction sensor can have any combination whatever of the characteristics set out above for the polarization module, namely, one or more receiving toroidal elements and for each receiving toroidal element:
one or more electrical windings, toroid in shape or not; and/or
a core around which is wound the at least one electrical winding, or no core; and/or
a ferromagnetic core toroid in shape.

According to an advantageous embodiment, the induction sensor can comprise at least one receiving toroidal element comprising:
a ferromagnetic ring or a ring made from ferromagnetic material provided to be placed around an electrical conductor electrically connected to at least one measurement electrode; and
at least one electrical winding positioned around said ferromagnetic ring in which the electrical signal provided by the induction sensor is induced.

The electrical winding is connected to the measurement electronics and provides said measurement electronics with the electrical signal relating to the electrode-object capacitance Cₒₑ and received by the induction sensor.

When the device according to the invention comprises an induction sensor, the measurement electronics can comprise a voltage amplifier, respectively a transimpedance amplifier, connected to said induction sensor and outputting a voltage relative to the voltage, respectively to the current, provided by said induction sensor, and in particular by the electrical winding of said induction sensor.

When it is intended to be connected to the measurement electrodes, the measurement electronics can comprise an amplifier of the transimpedance type configured to measure a current or a charge originating from at least one measurement electrode and output a voltage as a function of said current, respectively of said charge.

Regardless of the embodiment, the amplifier of the transimpedance type can comprise an operational amplifier (OA) of which:
a first input, for example the inverting input, is connected to the measurement electrode, respectively to the induction sensor and more particularly to the electrical winding of the induction sensor; and
a second input, for example the non-inverting input, is connected to the working potential; and
an output fed back to its first input by a feedback capacitor, and optionally a feedback resistor.

Under these conditions, the output of the OA provides an output voltage, denoted Vₛ, which is a function of the electrode-object capacitance Cₒₑ seen by the measurement electrode or electrodes which are connected to said first input or induction sensor.

The device according to the invention can also comprise a step of synchronous demodulation of an output voltage provided by the measurement electronics, and in particular the voltage Vₛ provided by the OA.

Such a demodulation step can be formed by a synchronous demodulator carrying out a synchronous demodulation of the voltage Vₛ provided by the measurement electronics with a carrier at the working frequency, and in particular identical to and/or in phase with the working alternating potential V_{g}.

According to another aspect of the invention, an appliance is proposed including:
a capacitive detection device according to the invention, and
at least one capacitive electrode electrically connected to an electrical conductor passing through the central opening of the at least one excitation toroidal element of the polarization module of said capacitive detection device.

According to the invention, at least one measurement electrode can comprise, or consist of, an additional capacitive electrode mounted on a portion of the appliance.

In this case, the appliance according to the invention is equipped with additional measurement electrodes which are added to the constituent elements of said appliance, for example in the form of a casing or a trim.

Alternatively, or in addition, at least one measurement electrode can comprise, or consist of:
an electrically conductive part of said appliance, such as a casing or a trim element of said appliance,
a constituent portion of said appliance, such as a segment,
a functional head, in particular interchangeable, equipping said appliance, or
all of said appliance.

In this case, the measurement electrode is formed by a constituent element of the appliance, without the addition of additional parts to said appliance. To be able to form an electrode that is distinct from other portions of the appliance, this constituent element must be electrically insulated from these other portions and connected to an electrical conductor passing through the polarization module. Conversely, constituent elements of the appliance electrically connected to one another form a single measurement electrode.

The appliance according to the invention can comprise at least one electrode, called guard electrode, polarized at the same potential as the at least one measurement electrode, at the working frequency.

This or these guard electrodes make it possible to avoid parasitic coupling capacitances between the measurement electrode or electrodes and the surroundings or the appliance.

Like the measurement electrode, the at least one guard electrode can be formed by an additional electrode mounted on the appliance, for example in a casing or a trim, between measurement electrodes and the internal structure of the appliance.

Alternatively, or in addition, at least one guard electrode can be formed by a constituent part, portion or functional head of the appliance according to the invention and electrically insulated from the measurement electrode.

At least one guard electrode can be polarized at the working alternating potential by an electrical source which is dedicated to it.

According to an advantageous alternative, at least one guard electrode can be polarized at the working alternating potential by the polarization module of the capacitive detection device with which the appliance according to the invention is equipped. In this case, the guard electrode is electrically connected to an electrical conductor which passes through the central opening of the excitation toroidal element or elements. As previously, this electrical conductor can be for example a track, or a wire or an electrical cable, or a conductive part of the appliance according to the invention.

In practice, all the elements of the appliance polarized at the working alternating potential by the polarization module and of which the coupling capacitances are not measured act as guard electrodes. Likewise, the distinct measurement electrodes act as guard electrodes for one another. Thus, according to an advantageous aspect of the invention, it is particularly easy to transform the whole appliance into a guard electrode, optionally even without adding dedicated electrodes, which makes it possible to implement capacitive measurement very simply and very effectively.

It should be noted that one or more measurement electrodes and/or one or more guard electrodes can be polarized at the working potential by one and the same electrical conductor passing through the polarization module, for example via electronic components.

The capacitive detection device of the appliance according to the invention can comprise a polarization module positioned:
around a base element, such as a segment, of said appliance serving to fix said appliance to an external support; or
between said base element and said external support, for example in the form of an intermediate part or a base, or
around one or a plurality of electrical cables connected to the appliance.

In the case that the polarization module is positioned around a base element, the portion of the appliance located downstream of the base element with the polarization module is polarized at the working potential. In the event that the polarization module is placed between the base element and the external support, it is the whole appliance which is polarized at the working potential.

In the case that the polarization module is placed around electrical cables connected to the appliance, all the electrical components connected to these electrical cables, and therefore potentially the whole appliance, as well as the sections of these cables located downstream of the polarization module are polarized at the working potential.

In general, it is preferable that the portions of the appliance polarized at the working potential are insulated from the ground, to ensure good operation of the capacitive measurement. However, a contact between a measurement electrode, or a portion of the appliance forming measurement electrode, and the ground would be detectable by the measurement electronics. Likewise, a contact between a portion of the appliance polarized at the working potential but not used as measurement electrode and the ground would be detectable by neighbouring measurement electrodes.

For example, when the appliance according to the invention is a robotized arm, the capacitive detection device of said robotized arm can comprise a polarization module placed around a segment located on the side of a base segment, and more particularly around the base segment, even more particularly between the base segment and an external support.

The capacitive detection device of the appliance according to the invention can comprise a first polarization module and a second polarization module positioned on either side of the at least one measurement electrode.

In other words, in this case, the at least one measurement electrode is placed between two polarization modules.

As described previously, the first polarization module and/or the second polarization module can be placed around at least one electrical conductor electrically connected to said at least one measurement electrode placed between the polarization modules. The electrical conductor can comprise in particular:
a track or an electric wire connected directly, or for example through electronics, to said measurement electrode, or
a part or a portion of the appliance equipped with the detection device according to the invention, electrically connected to said measurement electrode, or forming said measurement electrode, such as a trim element, a framework element, a segment in the case of a robot or a robotized arm, etc., or
a portion, or all, of the body of the appliance equipped with the detection device according to the invention.

The first polarization module and the second polarization module can have an identical architecture or different architectures.

According to a first embodiment, the second polarization module can be arranged so as to induce, in at least one electrical conductor passing through it, an alternating potential difference of the same value and opposite sign to the working alternating electrical potential, between an input of said second polarization module located on the side of the output of the first polarization module, and the output of said second polarization module.

In other words, in this case, the at least one measurement electrode is placed between two polarization modules and each polarization module induces an alternating potential difference equal to the working alternating potential in the direction towards the at least one working electrode. Put another way, in this first embodiment, the two polarization modules define between them a section of the appliance which is electrically polarized at the working potential, and which is positioned between two sections, on either side of the polarization modules, which are at the same potential, for example ground potential. This makes it possible for example to bring the distal section situated beyond the two polarization modules, and beyond the intermediate section with the capacitive detection to the ground. Thus, even if this distal section comes into contact with an element at the ground, the capacitive detection along the intermediate section is not disrupted.

In the particular case that the appliance according to the invention is a robotized arm, the capacitive detection device of said robotized arm can comprise a first polarization module placed around a segment located on the side of a base segment, and more particularly around the base segment, even more particularly between the base segment and an external support. The robotized arm can also comprise a second polarization module placed on the side of a distal segment of said robotized arm, and in particular around the distal segment, even more particularly between the distal segment and a functional head placed on said distal segment. Thus, the second polarization module makes it possible to use the functional head without the risk of disrupting the polarization of the at least one measurement electrode which is located between the first polarization module and the second polarization module. For example, the functional head can come into contact with the external surroundings and operate on an external object/support, having a potential different from the working alternating potential, without, however, disrupting the polarization of the at least one measurement electrode.

According to a second embodiment, the second polarization module can be arranged so as to induce, in at least one electrical conductor passing through it, an alternating potential difference different from the working alternating electrical potential, between an input of said second polarization module located on the side of the output of the first polarization module, and the output of said second polarization module.

In this case, the potential difference generated by the second polarization module, different from the working alternating potential and preferably at another frequency, can be used as a second working alternating electrical potential, different from a ground potential, at a second working frequency. This makes it possible to carry out a capacitive detection at a second working frequency, different from the first working frequency, using one and the same measurement electrode or different measurement electrodes. In fact:
a measurement electrode positioned on the intermediate section between the two polarization modules and electrically connected to a conductor passing through the first polarization module allows a capacitive measurement at the first working frequency;
a measurement electrode positioned on the distal section beyond the two polarization modules and electrically connected to a conductor passing through the second polarization module and optionally the first polarization module allows a capacitive measurement at the second working frequency;
a measurement electrode positioned both on the distal section beyond the two polarization modules and on the intermediate section between the two polarization modules, and connected to, or constituted by a conductor passing through the second and the first polarization module, allows both a capacitive measurement at the second working frequency on the distal section and a capacitive measurement at the first working frequency on the intermediate section, independently;
and in all cases, a disruption of the distal section, for example by connecting it to the ground, does not disrupt the measurements on the intermediate section.

This embodiment thus makes it possible to obtain a more robust capacitive detection for a detection zone at the level of the appliance according to the invention, or independent capacitive detections for different zones of the appliance according to the invention.

As indicated above, the capacitive detection device of the appliance according to the invention can comprise at least one induction sensor.

This induction sensor can be placed around one or a plurality of electrical conductors electrically connected to at least one measurement electrode.

Alternatively, or in addition, the induction sensor can be placed:
around a base element of the appliance according to the invention serving to fix said appliance to an external support;
between said base element and said external support, for example in the form of an intermediate part or a base; or
around one or a plurality of electrical cables connected to said appliance.

The induction sensor can be positioned around electrical conductors downstream of a polarization device, in the portion where these conductors are at the working potential. The induction sensor can also be positioned around electrical conductors upstream of a polarization device, in the portion where these conductors are not yet polarized at the working potential.

In all cases, the induction sensor allows a measurement of the current flowing in the electrical conductor or conductors passing through it (and also passing through the polarization device), and therefore a measurement of the overall coupling capacitance between the surroundings and the portions of the appliance polarized at the working potential and electrically connected to these conductive elements.

The appliance according to the invention can for example be a robot, a portion of a robot, mobile or fixed, and in particular a robotized arm.

Alternatively, the appliance according to the invention can be a display appliance comprising an electrical display screen.

In this case, the, or a, polarization module of the capacitive detection device can be placed around the cable or cables connected to said display screen, and if necessary, around a support arm, or strut, of said screen.

Generally, the appliance according to the invention can be any appliance capable of being equipped with a capacitive detection.

According to modes of implementation, the invention can comprise at least two appliances, in particular at least two robots, which use:
an identical working alternating electrical potential, so that said at least two appliances do not detect one another;
a different working alternating electrical potential, or with a different working frequency, so that said at least two appliances detect one another.

### DESCRIPTION OF THE FIGURES AND EMBODIMENTS

Other advantages and characteristics will become apparent on examination of the detailed description of an embodiment which is in no way limitative, and the attached drawings, in which:

FIG. 1 is a diagrammatic representation of the operating principle of a polarization module of a capacitive detection device according to the invention;

FIGS. 2a-2e are diagrammatic representations of different non-limitative embodiment examples of a polarization module of a capacitive detection device according to the invention;

FIGS. 3a-5 are diagrammatic representations of different non-limitative embodiment examples of a capacitive detection device according to the invention;

FIG. 6a is a diagrammatic representation of a non-limitative embodiment example of an induction sensor that can be implemented in a capacitive detection device according to the invention;

FIG. 6b is a diagrammatic representation of a non-limitative embodiment example of measurement electronics that can be implemented in a capacitive detection device according to the invention; and

FIGS. 7-13 are diagrammatic representations of different non-limitative embodiment examples of an appliance according to the invention.

It is of course understood that the embodiments that will be described hereinafter are in no way limitative. In particular, variants of the invention can be imagined comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In the figures, elements common to several figures keep the same reference.

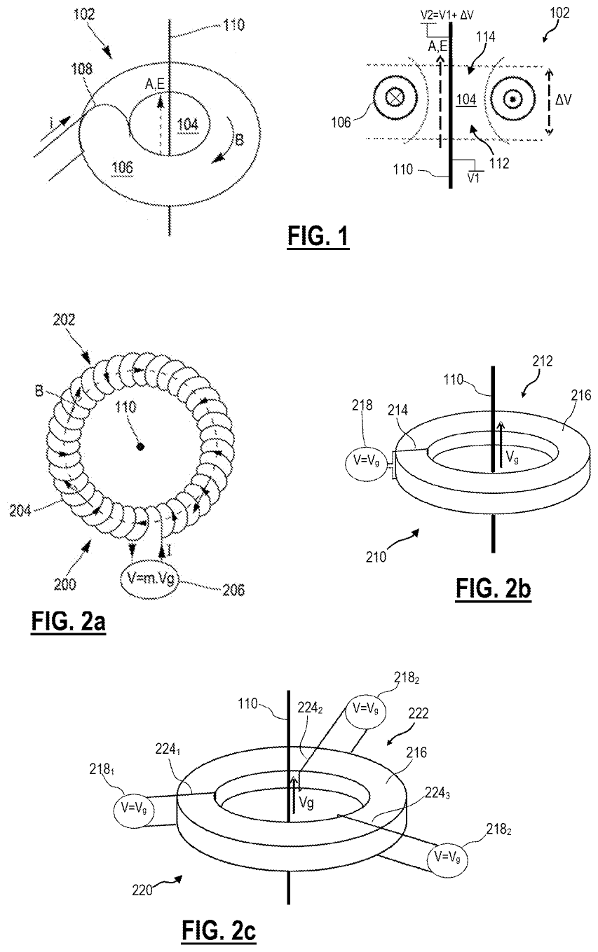

FIG. 1 is a diagrammatic representation of the operating principle of a polarization module of a capacitive detection device according to the invention.

FIG. 1 represents an excitation toroidal element 102 according to an isometric view and according to a cross-sectional view.

The excitation toroidal element 102 includes a central opening 104.

The excitation toroidal element 102 can have different architectures, non-limitative examples of which will be described hereinafter. In FIG. 1, the excitation toroidal element 102 is formed by a ferromagnetic core 106 having a circular cross section and a circular shape, for example made of ferrite, around which is wound a winding 108 including a single turn.

An electrical conductor 110 passes through the central opening 104 of the excitation toroidal element 102. The electrical conductor 110 enters the central opening 104 through an input 112 and leaves the central opening 104 through an output 114. This electrical conductor 110 can be, for example, an electrical cable, or an electrical track, for connecting a measurement electrode, or a conductive part of the structure of an appliance.

The flow of an alternating electrical current “i” in the electrical winding 108 generates a magnetic field B in the excitation toroidal element 102. This magnetic field B flows around the central opening 104, the space in which the electrical conductor 110 is located. The magnetic field B is associated with a magnetic field vector potential, A, defined by B=Rot(A) in the space surrounded by this magnetic field B. A temporal variation of this magnetic field vector potential A generates an electric field, E, following the same direction and according to the relationship E=∂A/∂t. This electric field E will establish a potential difference ΔV, along the field lines defined by the vector potential A.

As a result, the conductive element 110, passing through the central opening 104 containing the field lines, will see an electrical potential difference ΔV appear between the sections thereof respectively upstream and downstream of this space, i.e. between the section thereof located before the input 112 of the central opening 104 and the section thereof located after the output 114 of the central opening 104. Put another way, with respect to any reference whatever such as a general ground, if the conductor 110 is at the potential V1 at the level of the input 112 of the central opening 104, this same conductor 110 will be at the potential V2=V1+ΔV, at the level of the output 114 of the toroidal element 102.

It should be noted that this potential difference ΔV is superposed on all the potentials present in the conductor 110 which passes through the toroidal element 102. Thus, for example, if the potential V1 is a reference potential or general ground potential of the electronics upstream of the excitation toroidal element 102, the alternating potential V2=V1+ΔV becomes the reference potential downstream of the toroidal element 102.

Thus, it is possible to polarize any conductor passing through the toroidal element 102 at a working alternating potential, denoted V_{g}, by choosing ΔV=V_{g}.

The architecture of the excitation toroidal element 102, represented in FIG. 1, is in no way limitative and is given by way of example.

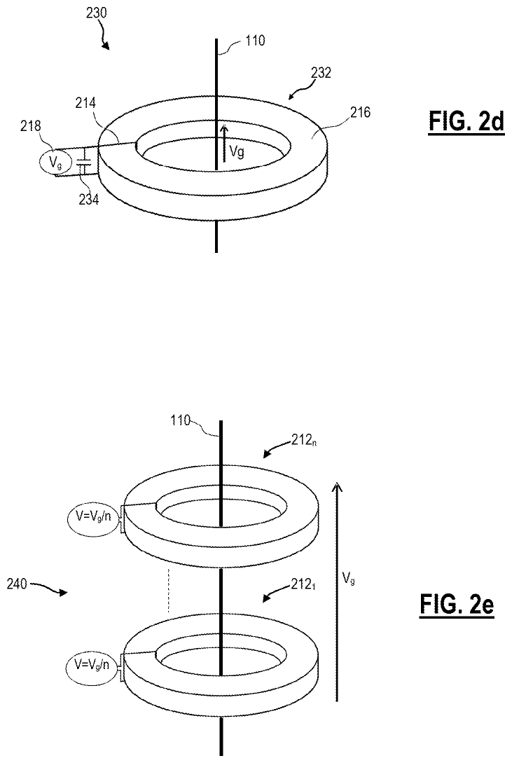

FIG. 2a is a diagrammatic representation, seen from above, of a non-limitative embodiment example of a polarization module of a capacitive detection device according to the invention.

The polarization module 200, represented in FIG. 2a, comprises an excitation toroidal element 202.

The excitation toroidal element 202 is formed by an electrical winding 204 in the shape of a toroid. More particularly, the electrical winding 204 has a shape having rotational symmetry, in particular circular.

The electrical winding 204 has a shape having a circular cross section. Alternatively, the electrical winding 204 can have a cross-section which is triangular, square, rectangular, etc.

In the example represented in FIG. 2a, the excitation toroidal element 202 does not include a core around which is wound the electrical winding 204. In other words, the electrical winding 204 is wound around air.

According to an alternative, the excitation toroidal element 202 can include a core around which is wound the electrical winding 204. In this case, the core can be made from a ferromagnetic material, or from a material which is not ferromagnetic.

The polarization module 200 also comprises an electrical source 206 supplying the electrical winding 204 with an alternating voltage V. Assuming that the electrical winding 204 comprises “m” turns, in order to induce an alternating potential difference equal to V_{g} in any electrical conductor 110 which passes through said excitation toroidal element 202, it is necessary to supply the electrical winding 204 with a voltage V=m·V_{g}, disregarding the coupling losses.

FIG. 2b is a diagrammatic representation of a non-limitative embodiment example of a polarization module of a capacitive detection device according to the invention.

The polarization module 200 comprises an excitation toroidal element 212.

The excitation toroidal element 212 of FIG. 2b comprises an electrical winding 214 wound around a ferromagnetic core 216.

In the example represented, the electrical winding 214 comprises a single turn. Of course, the electrical winding 214 can comprise more than one turn.

The polarization module 210 also comprises an electrical source 218 for supplying the electrical winding 214 with an alternating voltage V.

In the example represented in FIG. 2b, disregarding the losses, an excitation alternating potential difference V=V_{g} is applied at the terminals of the electrical winding 214 comprising a single turn. Thus, the polarization module 200 generates, in any electrical conductor 110 which passes through the excitation toroidal element 212, a potential difference ΔV=V_{g} between the input of the excitation toroidal element 212 and the output of the excitation toroidal element 212.

In general, as indicated above, if a voltage V is applied at the terminals of an electrical winding having “m” turns wound around the core 216, the potential difference induced on the electrical conductor 108 passing through the excitation toroidal element 212 would be ΔV=V/m. As a result, if a potential difference V_{g} is desired across the conductor 110 with an electrical winding comprising “m” turns wound around the core 216, then said electrical winding must be supplied with a voltage V=m·V_{g}.

In addition, according to a general definition, the voltage source 206 providing the voltage V “sees” an impedance which depends on the inductance of the electrical winding, which increases with the number of turns and the surface area encompassed by the turn or turns. The inductance Lₘ of an electrical winding having “m” turns is thus Lₘ=m² L, with L the inductance of a turn having the same surface area.

FIG. 2c is a diagrammatic representation of another non-limitative embodiment example of a polarization module of a capacitive detection device according to the invention.

The polarization module 220 of FIG. 2c comprises an excitation toroidal element 222.

The excitation toroidal element 222 of FIG. 2c comprises several, and in particular three, distinct electrical windings 224₁-224₃ wound around a ferromagnetic core 216.

In the example represented, each electrical winding 224₁-224₃ comprises a single turn. Of course, at least one of the electrical windings 224₁-224₃ can comprise more than one turn.

The electrical windings 224₁-224₃ represented in FIG. 2c are identical. Alternatively, at least two of the windings 224₁-224₃ can be different. In this case, the electrical windings including different numbers of turns are supplied with different alternating voltages.

In FIG. 2c, the electrical windings 224₁-224₃ are placed at a constant angular pitch of 120° in order to ensure a better distribution of the magnetic field. Of course, according to alternatives, the angular pitch between the windings may not be constant.

Moreover, the excitation toroidal element 222 can comprise a number of electrical windings different to three.

In the example represented in FIG. 2c, each electrical winding 224₁-224₃ is supplied with a voltage V=V_{g} such that an alternating potential difference equal to V_{g} is generated in any electrical conductor 110 which passes through the excitation toroidal element 222, since each electrical winding 224₁-224₃ includes a single turn. According to a general definition, in the example of FIG. 2c, if at least one of the electrical windings comprises “m” turns, then it would be necessary to supply said electrical winding with an alternating voltage V=V_{g}·m, in order to generate an alternating potential difference equal to V_{g} in any electrical conductor 110 which passes through the excitation toroidal element 222.

The polarization module 220 comprises, for each electrical winding 224₁-224₃, an electrical source, respectively 218₁-218₃, dedicated to supplying said electrical winding. Alternatively, at least two, in particular all the, electrical windings 224₁-224₃ can be supplied by a single electrical source common to all of said electrical windings.

It should be noted that, for “p” distinct electrical windings around one and the same ferromagnetic core, due to the couplings by mutual inductance, the inductance Lₚ of each electrical winding is given by Lₚ=p L, with L the inductance of an electrical winding which would alone be around said core. Thus, the inductance of p electrical windings in parallel, supplied by one and the same electrical source, corresponds to: p·L/p=L, namely the same inductance as that of a single winding. The power consumed by “p” electrical windings is therefore the same as the power consumed by a single electrical winding.

FIG. 2d is a diagrammatic representation of another non-limitative embodiment example of a polarization module of a capacitive detection device according to the invention.

The polarization module 230 of FIG. 2d comprises an excitation toroidal element 232.

The excitation toroidal element 232 of FIG. 2d comprises all the components of the excitation toroidal element 212 of FIG. 2b.

The excitation toroidal element 232 also comprises a capacitor 234 in parallel with the electrical winding 214, such that the electrical winding 214 forms, with said capacitor 234, a resonant circuit. The capacitance of the capacitor 234 and the inductance value of the electrical winding 214 are chosen such that the resonant frequency of the resonant circuit is equal to the working frequency, denoted f_{g}, i.e. to the working potential frequency V_{g}.

The setting in resonance, via the addition of a capacitor 234, makes it possible to increase the impedance and therefore reduce the supply current of the winding 214. In this case, the electrical source 206 must be tuned to the frequency f_{g} given by the following relationship

$${f}_{g} = \frac{1}{2 π \sqrt{C . Leq}} ,$$

with C the capacitance of the capacitor 234 and Leq the resulting inductance.

This configuration, illustrated in FIG. 2d with a single electrical winding can of course be used in each of the examples given in FIGS. 2a-2c, with each of the excitation toroidal elements 202, 212 and 222.

As explained previously with reference to FIG. 2c, the inductance of each of the windings, with “p” windings, is Lₚ=p L, with L the inductance of an electrical winding which would alone be around a toroidal core. If C is the capacitance in order to obtain a resonance at the excitation frequency f_{g} with a single inductance winding L, the capacitance Cₚ to be placed in parallel with each of the p coupled windings in order to obtain the same resonant frequency is Cₚ=C/p, which gives

$${f}_{g} = \frac{1}{2 π \sqrt{\frac{C}{p} . p . L}} .$$

Each of the polarization modules 200, 210, 220 and 230 which have just been described comprises a single excitation toroidal element.

Alternatively, a polarization module can comprise several identical or different excitation toroidal elements placed in a cascade.

FIG. 2e is a diagrammatic representation of another non-limitative embodiment example of a polarization module of a capacitive detection device according to the invention.

The polarization module 240, represented in FIG. 2e, comprises “n” excitation toroidal elements 212₁-212ₙ, placed in a cascade in series along an electrical conductor 110 which passes through each of said excitation toroidal elements 212₁-212ₙ.

In the polarization module 240, the n excitation toroidal elements are identical. Alternatively, the polarization module 240 can comprise at least two different excitation toroidal elements.

Each of the n excitation toroidal elements 212₁-212ₙ of the polarization module 240 is identical to the excitation toroidal element 212 of FIG. 2b. Alternatively, at least one of the excitation toroidal elements can be any one of the excitation toroidal elements 202, 222 or 232.

The electrical winding of each excitation toroidal element 212, is supplied by an independent electrical source. Alternatively, the electrical windings of at least two of the, in particular of all the, excitation toroidal elements 212₁-212ₙ can be supplied by a single electrical source.

In general, when a polarization module comprises several excitation toroidal elements in a cascade, each excitation toroidal element will contribute to a portion ΔVᵢ of the increase of the targeted potential ΔV=V_{g}, with ΔV=ΣₙΔVᵢ. Moreover, each excitation toroidal element with one or more windings with “m” turns contributes to a potential difference ΔVᵢ=V/m, disregarding the losses. The total potential difference obtained is n times the potential difference of each excitation toroidal element (V/m).

Thus, in the example represented in FIG. 2e, each excitation toroidal element 212ᵢ contributes to a portion ΔVᵢ of the increase of the targeted potential ΔV=V_{g}. In addition, as each excitation toroidal element 212ᵢ comprises a single electrical winding with a single turn, then each electrical winding is supplied with an alternating voltage V=ΔVᵢ=V_{g}/n.

When all the “n” electrical windings are supplied by a single electrical source, considering that all the “n” electrical windings have the same geometry or at least the same surface area and include “m” turns, the inductance L_{T} of all the electrical windings “seen” in parallel by one and the same voltage source is: L_{T}=m²L/n, or L_{T}=nL for m=n. It follows that the power consumed in this configuration is less than for an excitation toroidal element including a single electrical winding.

The configuration shown in FIG. 2e can be implemented with a plurality of electrical windings in parallel for each toroidal element, for a better homogeneity of the potential differences induced without change with regard to the potential difference ΔV generated and the power consumed.

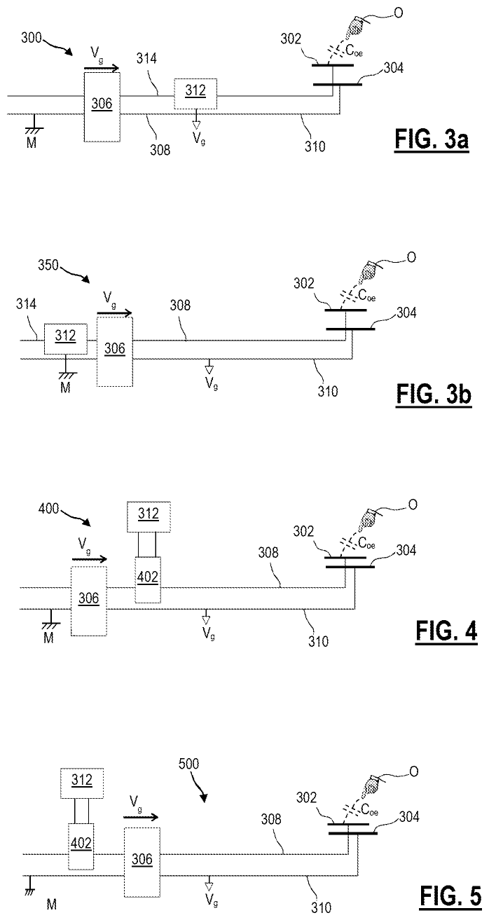

FIG. 3a is a diagrammatic representation of a non-limitative embodiment example of a capacitive detection device according to the invention.

The capacitive detection device 300, represented in FIG. 3a, comprises at least one electrode 302, called measurement electrode, and optionally at least one electrode 304, called guard electrode, to electrically guard the measurement electrode 302. This guard electrode 304 can for example be placed under the measurement electrode 302 on the opposite side to the detection zone/surface.

The detection device 300 comprises at least one polarization module 306 for polarizing the measurement electrode 302, and the guard electrode 304 where appropriate, at a working alternating potential V_{g}, different from a ground potential, denoted M, at a working frequency, denoted f_{g}. The polarization module 306 can be any one of the polarization modules 200, 210, 220, 230 or 240 of FIGS. 2a-2e.

The polarization module 306 carries out a polarization of the measurement electrode 302 by induction of an alternating potential difference, equal to the working alternating potential V_{g}, in an electrical conductor 308 electrically connected to said measurement electrode 302, and passing through the polarization module 306. Similarly, the polarization module 306 polarizes the guard electrode 304 by induction of an alternating potential difference, equal to the alternating working potential V_{g}, in an electrical conductor 310 electrically connected to said guard electrode 304, and passing through the polarization module 306.

In general, the polarization module 306 polarizes all of the conductors which pass through it at the working alternating potential V_{g}. Thus, the guard electrode 304 can represent any portion of the appliance polarized at the working potential V_{g} and not used as measurement electrode 302.

The detection device 300 also comprises measurement electronics 312, connected to the measurement electrode 302 and configured to output a signal proportional to an object-electrode coupling capacitance, denoted Cₒₑ, between the measurement electrode 302 and an object O, such as a hand approaching or in contact with a detection surface.

In the capacitive detection device 300 as illustrated, the measurement electronics 312 are placed downstream of the polarization module 306, between the polarization module and the measurement electrode. The measurement electrode 302 is polarized at the working potential V_{g} via these measurement electronics 312, which are themselves preferably referenced to the working potential V_{g}. The measurement electrode 302 and the guard electrode 304 are polarized at the working potential V_{g} by the same electrical connection 308 passing through the polarization module 306. The output of the measurement electronics 312 is effected by an electrical connection 314 which also passes through the polarization module 306 but in the opposite direction, which makes it possible to transform a measurement signal at the output of the measurement electronics 312 referenced to the working potential into a measurement signal referenced to the ground M after passing into the polarization module 306.

FIG. 3b is a diagrammatic representation of another non-limitative embodiment example of a capacitive detection device according to the invention.

The capacitive detection device 350, represented in FIG. 3b, differs from the device 300 in that the measurement electronics 312 are placed upstream of the polarization module 306 such that the polarization module 306 is located between the measurement electrode 302 and the measurement electronics 312. In this case, the measurement electrode 302 is polarized at the working potential V_{g}, and connected to the measurement electronics 312, by a conductor 308 which passes through the polarization module. The measurement electronics 312 are preferably referenced to the ground potential M and directly output, across the electrical connection 314, a measurement signal referenced to the ground M.

In the examples illustrated in FIGS. 3a and 3b, and more generally in all the examples that will be described, at least one electrical conductor 308, respectively 310, passing through the polarization module 306, and electrically connected to at least one measurement electrode 312, respectively to a guard electrode 304, can be:
a track or an electric wire of said electrode, or
a part or a portion of an appliance equipped with the detection device 300, in electrical contact with said electrode, such as a trim element, a framework element, a segment in the case of a robot or a robotized arm, etc., or
a portion or all of the body of an appliance equipped with the detection device 300.

In the examples illustrated in FIGS. 3a and 3b, and more generally in all the examples that will be described, at least one measurement electrode 302, respectively one guard electrode 304, can comprise, or consist of:
an additional capacitive electrode mounted on a portion of an appliance equipped with the detection device 300;
an electrically conductive part of said appliance, such as a casing or a trim element,
a constituent portion of said appliance, such as a segment,
a functional head, in particular interchangeable, with which said appliance is equipped, or
all of said appliance.

FIG. 4 is a diagrammatic representation of another non-limitative embodiment example of a capacitive detection device according to the invention.

The capacitive detection device 400, represented in FIG. 4, comprises all the components of the detection device 350 of FIG. 3b.

The capacitive detection device 400 also comprises an induction sensor 402 placed between the measurement electronics 312 and an electrical conductor 308 electrically connected to the measurement electrode 302. In this capacitive detection device 400, the induction sensor 402 is also positioned between the measurement electrode 302 and the polarization device 306.

In particular, the induction sensor 402 comprises at least one toroidal element, called receiving toroidal element, including one central opening passed through by the at least one electrical conductor 308.

The current flowing in the electrical conductor 308, passing through the central opening of the induction sensor 402, induces an alternating signal in an electrical winding of the receiving toroidal element of the induction sensor 402, as illustrated below. This signal is a function of the capacitance Cₒₑ seen by the measurement electrode. This signal can then be measured by the measurement electronics 312 connected to the induction sensor 402.

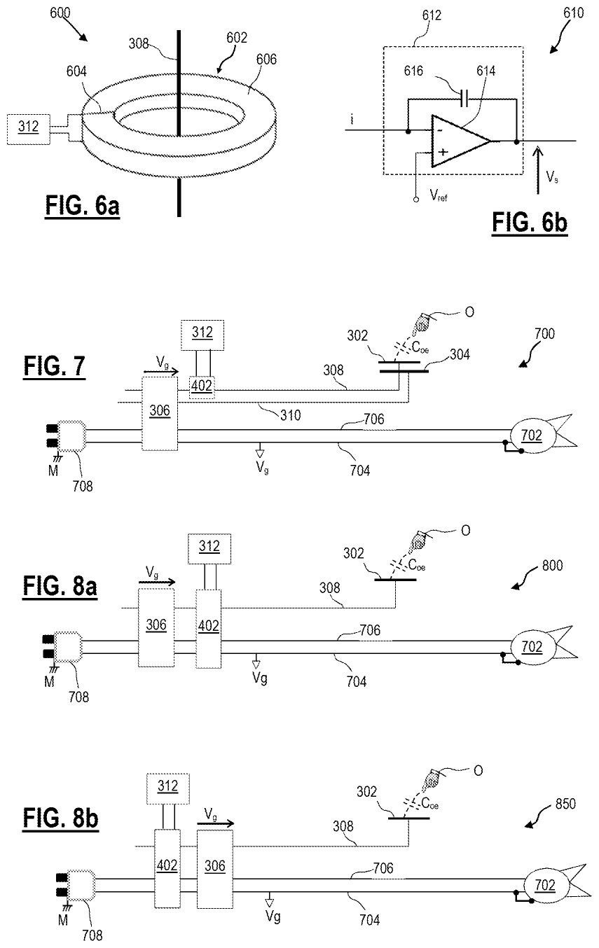

A non-limitative example of an induction sensor 402 is given below, with reference to FIG. 6a.

FIG. 5 is a diagrammatic representation of another non-limitative embodiment example of a capacitive detection device according to the invention.

The capacitive detection device 500, represented in FIG. 5, comprises all the components of the detection device 400 of FIG. 4.

The capacitive detection device 500 differs from the detection device 400 in that the induction sensor 402 and the measurement electronics 312 are placed upstream of the polarization module 306 such that the polarization module 306 is located between the measurement electrode 302 and the induction sensor 402 and the measurement electronics 312.

FIG. 6a is a diagrammatic representation of a non-limitative embodiment example of an induction sensor that can be implemented in a capacitive detection device according to the invention.

The induction sensor 600 of FIG. 6 can be the induction sensor 402 of FIGS. 4 and 5.

In the example represented, and in a manner that is in no way limitative, the induction sensor 600 comprises a receiving toroidal element 602, including a central opening passed through, in the example illustrated, at least by the electrical conductor 308 connected to the at least one measurement electrode 302.

The receiving toroidal element 602 is identical to, or can be produced in the same manner as, the excitation toroidal element 212 of FIG. 2b. It comprises an electrical winding 604 wound around a ferromagnetic core 606. The electrical winding 604 is connected to the measurement electronics 312, which can be the measurement electronics 312 of FIGS. 3a-5.

In the example represented, the electrical winding 604 comprises a single turn. Of course, the electrical winding 604 can comprise more than one turn.

In general, the induction sensor 600 can comprise a receiving toroidal element, or a combination of several receiving toroidal elements placed in a cascade, including a central opening passed through at least by an electrical conductor connected to at least one measurement electrode 302.

In a manner that is in no way limitative, at least one receiving toroidal element can be formed by:
at least one electrical winding toroid in shape, and in particular with rotational symmetry, and the cross section of which can be circular, square, rectangular, etc. in shape, such as for example the toroidal element 202 of FIG. 2a,
at least one core, in particular ferromagnetic, each including one or more electrical windings wound around said core, and each including at least one turn, such as for example any one of the toroidal elements 212, 222 or 232 of FIGS. 2b-2d.

FIG. 6b is a diagrammatic representation of a non-limitative embodiment example of measurement electronics that can be implemented in a capacitive detection device according to the invention.

The measurement electronics 610, represented in FIG. 6b, can be, or be comprised in, the measurement electronics 312 of FIGS. 3-5.

In the example represented, and in a manner that is in no way limitative, the measurement electronics 610 comprise a current, or charge, detector 612, for example of the transimpedance amplifier type, which measures the current generated at the working frequency of the potential V_{g} by the capacitive coupling between the measurement electrode 302 and the object O. This transimpedance amplifier can comprise an operational amplifier (OA) 614 with:

the inverting input (“−”) connected to the measurement electrode 302, or to the induction sensor 402, and receiving the current i to be measured;

the non-inverting input (“+”) connected to a reference potential V_{ref} corresponding, according to the configurations, to the working potential V_{g} or to the ground potential M; and

the output fed back to its inverting input, with a feedback capacitor 616, and optionally a resistor (not represented).

Under these conditions, the output of the OA 614 provides a voltage Vₛ as a function of the current i and therefore of the capacitance Cₒₑ. The output of the OA 614 can be connected to a step of synchronous detection, which makes it possible to obtain, by synchronous demodulation with a carrier corresponding to the working potential V_{g}, the capacitive signal at the working frequency.

In the capacitive detection device 300, the measurement electronics 312 utilize measurement electronics 610 with the inverting input (“−”) connected to the measurement electrode 302 and the non-inverting input (“+”) connected to the working potential V_{g}. Preferably, this measurement electronics 312 is also referenced by its electric power supplies to the working potential V_{g}, to avoid internal leakage capacitances. The output of these measurement electronics is effected as explained previously by the electrical connection 314 which also passes through the polarization module 306 but in the opposite direction, which makes it possible to transform a measurement signal Vₛ at the output of the measurement electronics 312 referenced to the working potential Vg into a measurement signal Vₛ referenced to the ground M after passing into the polarization module 306. It should be noted that passing through the polarization module does not modify the measurement signal Vₛ with respect to the reference under consideration (Vg or M).

In the capacitive detection device 350, the measurement electronics 312 utilize measurement electronics 610 with the inverting input (“−”) connected to the measurement electrode 302 through the polarization module, and the non-inverting input (“+”) connected to the ground potential M. The output of these measurement electronics directly produces a measurement signal Vₛ referenced to the ground M. Preferably, these measurement electronics 312 are also referenced by its electric power supplies to the ground potential M.

In the capacitive detection devices 400 and 500, the measurement electronics 312 utilize measurement electronics 610 with the inverting input (“−”) and the non-inverting input (“+”) connected respectively to the two ends of a winding of the induction sensor 402, so as to measure the current which is flowing in this winding by induction. The inverting input (“−”) can also be connected at a potential which determines the reference potential of these electronics, or for example at the working potential Vg in the capacitive detection device 400, and the ground potential M in the capacitive detection device 500, so as to limit the parasitic coupling capacitances.

Alternatively, and when the capacitive detection device comprises an induction sensor, the measurement electronics can be, or comprise, a voltage amplifier connected to said induction sensor and outputting a voltage relative to the voltage provided by said induction sensor.

FIG. 7 is a partial diagrammatic representation of a non-limitative embodiment example of an appliance according to the invention.

The appliance 700, represented in FIG. 7, is very simplified and can be any type of appliance, such as a robot, a robotized arm, any type of machine, etc.

The appliance 700 comprises one or more electrical members. In the example represented, the appliance 700 comprises a motorized gripping member 702, such as a motorized gripper, supplied by electrical lines 704-706 connected to an electrical plug 708. The electrical plug 708 is intended to be connected to an electrical interface external to the appliance 700 providing the electrical energy supplying the gripping member 702.

The appliance 700 is equipped with a capacitive detection device according to the invention, such as for example the device 400 of FIG. 4. As described above, the device 400 comprises a measurement electrode 302, an optional guard electrode 304, a polarization module 306, an induction sensor 402 and measurement electronics 312. The polarization module 306 polarizes the measurement 302 and guard 304 electrodes, at the working potential V_{g}, by inducing an alternating potential difference equal to the working potential V_{g} in the electrical conductors 308 and 310 which pass through it and which are connected to these electrodes 302 and 304.

In the appliance 700, the presence of electrical members polarized at a potential other than the guard potential V_{g}, in proximity to the measurement electrode 302, or to any electrical conductor which is connected to it, can disrupt the capacitive detection, by creating parasitic capacitances. Yet the electrical plug 708, the conductors 704 and 706 and the gripping member 702 are at the reference potential M which is the input potential of the appliance 700 or the potential of the external source, and generally a general ground potential. As a result, these electrical members 702-708 risk disrupting the capacitive detection.

In order to avoid this disruption, the polarization module 306 is placed, not only around the electrical conductors 308 and 310 which are connected to the electrodes 302 and 304, but also around the electrical conductors 704 and 706 which are connected to the gripping member 702. Thus, the polarization module 306 induces an alternating potential difference equal to the guard potential V_{g} both in the conductors 308 and 310, but also in the conductors 704 and 706. In other words, the polarization module 306 superposes the working potential V_{g} on the other potentials, or signals, already present in the conductors 704 and 706, over all the portion of these conductors 704 and 706 located downstream of the polarization module 306, i.e. between the polarization module 306 and the motorized gripping member 702.

Thus, the conductors 704 and 706 and the gripping member 702 are at the guard potential V_{g}. As a result, at the working frequency f_{g} of the working potential V_{g}, the conductors 704 and 706, and the gripping member 702, are at the same potential as the measurement electrode 302 and therefore do not disrupt the capacitive detection.

It should be noted that the working potential V_{g} is superposed on all the other potentials present in the conductors 704 and 706, and on all the signals circulating in the conductors 704 and 706, including at the reference potential of these signals. Thus, these signals are not affected by the superposition of the working potential V_{g} in the conductors 704 and 706 such that the operation of the gripping member 702 is not impacted.

The simplified example which has just been described with a single electrical member can potentially be applied to all the electrical members, and to all the electrically conductive parts, of an electrical or electronic appliance. The polarization module of the capacitive detection device according to the invention can be used to polarize one or more electrical members of an appliance, one or more electrically conductive parts, but also a portion or all of an appliance at the working potential.

Thus, according to a general definition, any conductive element capable of establishing a parasitic capacitance able to disrupt the capacitive detection can be polarized at the working potential V_{g}, such as for the gripping member 702 and the electrical conductors 704 and 706. In this manner, all these elements which are polarized but not used to carry out the capacitive measurement operate as guard electrodes 304.

The appliance 700 comprises the detection device 400 of FIG. 4 which allows a measurement of the coupling capacitance specifically between a measurement electrode 302 and the surroundings.

Of course, the appliance 700 can be equipped with another capacitive detection device according to the invention, such as for example any one of the devices 300, 350 or 500, or any one of their alternatives.

FIG. 8a is a partial diagrammatic representation of another non-limitative embodiment example of an appliance according to the invention.

The appliance 800, represented in FIG. 8a, comprises all the elements of the appliance 700 of FIG. 7, except the guard electrode 304 and the conductor 310.

In addition, unlike the appliance 700, in the appliance 800, the induction sensor 402 is placed around, not only the electrical conductor 308 connected to the measurement electrode 302, but also around the electrical conductors 704 and 706 connected to the gripping member.

According to a general definition, according to the invention, any conductive element capable of establishing a capacitance with another element or the surroundings can be passed through the induction sensor 402.

This embodiment makes it possible to monitor the general state of the elements polarized at the working potential V_{g}, in order to detect coupling capacitances between the surroundings and the conductive elements, for example the conductive wires 704 and 706 or the measurement electrode 302. In fact, in the absence of any coupling capacitances, the currents flowing in the conductors 704 and 706 cancel one another out in the induction sensor 402. Similarly, when no object is detected by the measurement electrode 302, no current flows in the conductor 308. As a result, in the absence of coupling capacitances with the surroundings, the sum of the currents passing through the central opening of the sensor is zero, and the induction sensor 402 should not detect anything. However, in the case of capacitive coupling between an object and the measurement electrode 302, or elements connected to the conductors 704 and 706, all of the currents flowing in the conductors passing into the induction sensor 402 do not cancel one another out, which induces a non-zero signal in this induction sensor 402.

Thus, this embodiment makes it possible to carry out an overall capacitive detection with all of the elements polarized at the potential V_{g} and passing through the induction sensor 402, which can relate to a portion or even the whole appliance. In this case, all of the elements polarized at the potential V_{g} and passing through the induction sensor 402 behave like a measurement electrode 302.

Alternatively, detection circuits associated with each element can also be used to measure, individually, the currents generated by the coupling capacitances, as illustrated with the capacitive detection device 400.

In the appliance 800, the induction sensor 402 is positioned between the measurement electrode 302 and the polarization device 306, like in the capacitive detection device 400.

FIG. 8b is a partial diagrammatic representation of another non-limitative embodiment example of an appliance according to the invention.

The appliance 850, represented in FIG. 8b, comprises all the elements of the appliance 800 of FIG. 8a.

The appliance 850 differs from the appliance 800 in that the induction sensor 402 and the measurement electronics 312 are placed upstream of the polarization module 306 such that the polarization module 306 is located between the measurement electrode 302 and the induction sensor 402 and the measurement electronics 312. The induction sensor 402 is placed around, not only the electrical conductor 308 connected to the measurement electrode 302, but also around the electrical conductors 704 and 706 connected to the gripping member. This configuration also allows an overall measurement of capacitive coupling with all of the elements polarized at the potential V_{g} and passing through the induction sensor 402. Its operation is the same as that of the capacitive detection device 500.

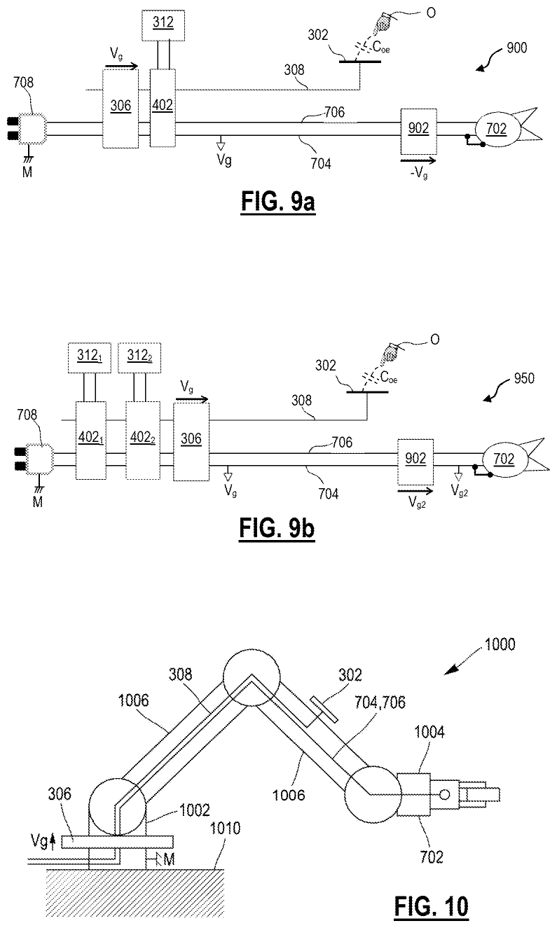

FIG. 9a is a partial diagrammatic representation of another non-limitative embodiment example of an appliance according to the invention.

The appliance 900, represented in FIG. 9a, comprises all the elements of the appliance 800 of FIG. 8a.

In the appliance 900, the capacitive detection device comprises, in addition to the polarization module 306, a second polarization module 902. The second polarization module 902 can have an architecture identical to, or different from, that of the polarization module 306. The second polarization module 902 can be any one of the polarization modules 200, 210, 220, 230 or 240 of FIGS. 2a-2e.

The second polarization module 902 is placed around the conductors 704 and 706, just before the motorized gripping member 702.

In the example represented in FIG. 9a, the second polarization module 902 is arranged to induce an alternating potential difference equal to the working potential V_{g} but having the opposite sign, i.e. an alternating potential difference equal to −V_{g}, between its input located on the side of the polarization module 306 and of the measurement electrode 302 and its output located on the side of the gripping member 702. Thus, the portion of each conductor 704 and 706 located between the polarization modules 306 and 902 is polarized at the working potential V_{g}, while the portions of these conductors 704, 706 and the gripping member 702 located on the side opposite the second polarization module 902 are brought to the initial potential, for example ground potential, from before the first polarization module 306.

Thus, the gripping member 702 can come into contact with an object or a surface at the ground potential M, or at any other potential, without however disrupting the polarization of the electrical conductors 704 and 706 at the potential V_{g} in the portion located between the polarization modules 306 and 902. The induction sensor 402, operating at the working frequency V_{g}, thus makes it possible to measure the coupling capacitance with all the conductors which pass through it, and which operate as measurement electrode, in the section thereof between the polarization modules 306 and 902, without being affected by a possible contact with the ground beyond the second polarization module.

FIG. 9b is a partial diagrammatic representation of another non-limitative embodiment example of an appliance according to the invention.

The appliance 950, represented in FIG. 9b, comprises all the elements of the appliance 900 of FIG. 9a.

In this embodiment, the second polarization module 902 can be arranged to induce an alternating potential difference equal to a second working potential, denoted V_{g2}, having a frequency f_{g2} different from the frequency f₉ of the working potential V_{g}, between its input located on the side of the polarization module 306 and of the electrodes 302 and 304 and its output located on the side of the gripping member 702.

Thus, the gripping member 702 and the portions of the conductors 704 and 706 located between the second polarization module 902 and the gripping member 702, are polarized at the second working potential V_{g2}, different from the ground potential M and different from the first working potential V_{g}, at the second working frequency f_{g2}. This makes it possible to use the gripping member 702 as measurement electrode to carry out a capacitive detection at the second working frequency f_{g2}. Moreover, to avoid the gripping member 702 also operating as measurement electrode at the first working frequency f₉, it is also possible to superpose on the potential V_{g2} a potential −V_{g} in the second polarization module 902, as previously.

In the example illustrated in FIG. 9b, the appliance 950 comprises two induction sensors 402₁ and 402₂ respectively coupled to detection electronics 312₁ and 312₂, and arranged respectively to carry out a capacitive detection at the first working frequency f_{g} and at the second working frequency f_{g2}. The induction sensors 402₁ and 402₂ can be positioned around the same conductors, for example in the portion referenced to the ground, as illustrated. As a function of the working frequencies of the measurement electronics, they will be sensitive to the capacitive couplings with the conductors between the two polarization modules 306, 902, and/or beyond the second polarization module 902.

According to other modes of implementation, one and the same induction sensor 402 and one and the same measurement electronics 312 can be used simultaneously or sequentially for the capacitive detection at the working frequency f_{g}, and at the second working frequency f_{g2}. Alternatively, it is possible to use an induction sensor and/or measurement electronics with or without an induction sensor, dedicated to the capacitive detection at the second working frequency f_{g2}.

In addition, the embodiments described in FIGS. 9a and 9b can be combined with the embodiment of FIG. 7 by placing an induction sensor 402 only around a conductor 308 connected to the measurement electrode 302.

As indicated above, the guard electrode 304 is optional in all the examples described. Or more accurately, all of the elements polarized at the working potential and not used as measurement electrode act as guard electrode.

Moreover, the use of the induction sensor 402 is also optional in all the examples described. It is in fact possible to connect the measurement electronics directly to the conductor 308, without using an induction sensor.

FIG. 10 is a diagrammatic representation of another non-limitative embodiment example of an appliance according to the invention.

The appliance 1000, represented in FIG. 10, is a robotized arm including a base segment 1002 and a distal segment 1004 equipped with a functional head, which can for example be the motorized gripping member 702 of FIGS. 7, 8a, 8b, 9a and 9b. The robotized arm includes two other intermediate segments 1006 and 1008 placed between the base segment 1002 and the distal segment 1004.

In particular, the robotized arm 1000 can be any one of the appliances 700, 800, 850, 900 or 950 of FIGS. 7, 8a, 8b, 9a and 9b.

The robotized arm 1000 is placed on a surface 1010, which is at the ground potential M.

The robotized arm 1000 is equipped with a capacitive detection device according to the invention, which can be any one of the detection devices of FIG. 3a, 3b, 4, 5, 7, 8a, 8b, 9a or 9b.

In FIG. 10, the capacitive detection device is partially represented. Thus, only the polarization module 306, the measurement electrode 302 and the conductor 308 can be seen in FIG. 10.

The polarization module 306 is placed around the base segment 1002 of the robotized arm 1000. Thus, all of the electrical conductors which pass through the polarization module 306, as well as all the electrical conductors which are in contact with them, are polarized at the guard potential Vg, downstream of the polarization module 306.

In particular, all the portion of the robotized arm 1000, which is located downstream of the polarization module 306 is polarized at the guard potential V_{g}.

FIG. 11 is a diagrammatic representation of another non-limitative embodiment example of an appliance according to the invention.

The appliance 1100, represented in FIG. 11, is a robotized arm including all the elements of the robotized arm 1000 of FIG. 10.

In the example of FIG. 11, unlike the robotized arm 1000 of FIG. 10, the polarization module 306 is placed between the surface 1010 and the base segment 1002.

In this example, the polarization module 306 forms a base for the robotized arm 1100.

Thus, all of the robotized arm 1100 is polarized at the guard potential V_{g}.

In another implementation example, the robotized arm is insulated from the ground, for example by virtue of an insulating baseplate, and the polarization module 306 is positioned around the whole electric power supply and data cables connected to the robot.

Thus, in the same way as before, all of the robotized arm is polarized at the guard potential V_{g}.

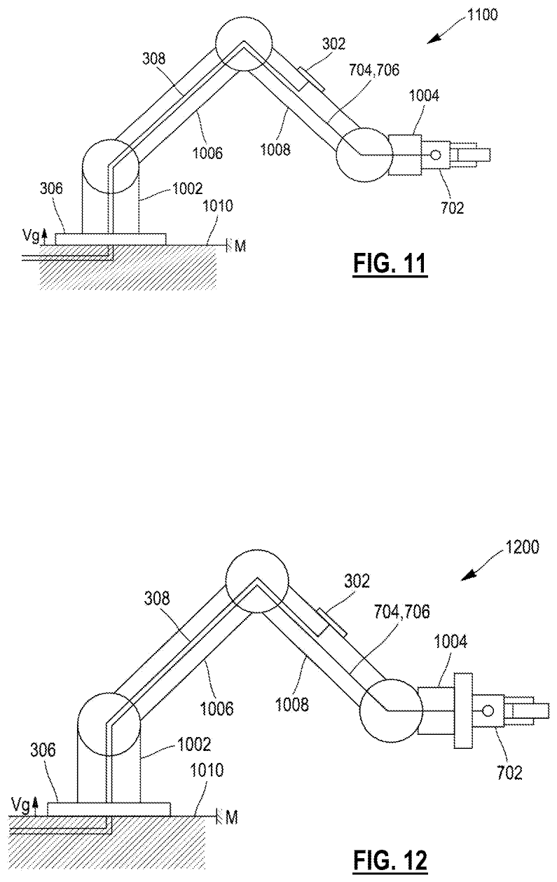

FIG. 12 is a diagrammatic representation of another non-limitative embodiment example of an appliance according to the invention.

The appliance 1200, represented in FIG. 12, is a robotized arm including all the elements of the robotized arm 1100 of FIG. 11.

The robotized arm 1200 comprises, in addition to the polarization module 306, a second polarization module, for example the polarization module 902 of FIGS. 9a and 9b.

In the example represented, the second polarization module 902 is placed between the distal segment 1004 of the appliance 1200, and the functional head 702.

Thus, all of the robotized arm 1200 is polarized at the guard potential V_{g}, except the functional head 702. The functional head 702 can be used as detection electrode at a second detection frequency f_{g2}, as described with reference to FIG. 9b, or brought to a ground potential M as described with reference to FIG. 9a.

Alternatively, to that which is represented in FIG. 12, the second polarization module 902 can be placed around another segment of the robotized arm 1200, such as for example around the distal segment 1004, and not between the distal segment 1004 and the functional head 702.

Of course, according to alternatives that are not represented, it is possible to use a second polarization module 902, in the robotized arm 1000 of FIG. 10 or in the robotized arm 1100 of FIG. 11, either between the distal segment 1004 and the functional head 702, or around a segment of the robotized arm such as the distal segment 1004.

The appliance according to the invention is not limited to a robotized arm and can be any electrical or electronic appliance.

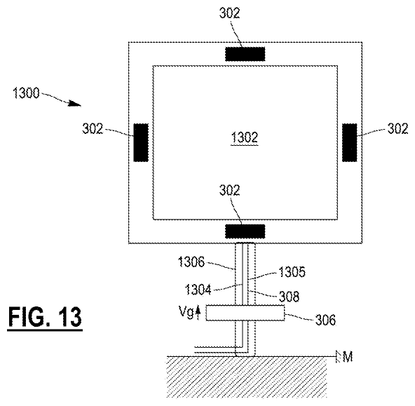

FIG. 13 is a diagrammatic representation of another non-limitative embodiment example of an appliance according to the invention.

The appliance 1300, represented in FIG. 13, is an electronic display appliance comprising a display screen 1302 supplied by an electric power supply cable 1304, communication or data cables 1305 and a support strut 1306 of said display screen 1302.

The display appliance 1300 comprises a capacitive detection device according to the invention, which can be any one of the detection devices of FIG. 3, 4, 5, 7, 8a, 8b, 9a or 9b.

In FIG. 13, the capacitive detection device is partially represented. Thus, only the polarization module 306, measurement electrodes 302 and the conductor 308 can be seen in FIG. 13.

The measurement electrodes 302 are placed on the frame of the display screen 1302, for example at the rate of one measurement electrode 302 per side.

The polarization module 306 is placed around the support strut 1306, and around the electric power supply 1304 and data 1305 cables. Thus, all of the electrical conductors which pass through the polarization module 306, as well as all the electrical conductors which are in contact with them, are polarized at the guard potential V_{g}, downstream of the polarization module 306.

In particular, all the portion of the display device which is located downstream of the polarization module 306 is polarized at the guard potential V_{g}, without any particular modification.

Of course, the polarization module can, according to an alternative, constitute a base on which the display device 1300 is placed, similarly to that which is described with reference to the robotized arm of FIG. 11 or 12.

In all the examples described, the or each measurement electrode is formed by an additional electrode mounted on the appliance.

According to alternatives that are not represented, at least one measurement electrode can be formed by a constituent portion of the appliance, or the whole appliance. For example in the case of a robotized arm, at least one measurement electrode can be formed by a trim element of the robotized arm, a segment of the robotized arm, all of the robotized arm, etc. In the context of a display device, at least one measurement electrode can be formed, for example, by an electrically conductive frame of the display screen, or the whole display screen.

Of course, the invention is not limited to the examples detailed above.

1. A device for capacitive detection of an object (o), comprising:
at least one polarization module configured to polarize at least one measurement electrode at an alternating electrical potential (V_{g}), called working potential, different from a ground potential (M); and
measurement electronics configured to measure a signal relating to a capacitance (Cₒₑ), called object-electrode capacitance, seen by said at least one measurement electrode, at a working frequency;
at least one polarization module comprises at least one toroidal element, called excitation toroidal element, with a central opening:
provided to be placed around at least one electrical conductor electrically connected to said at least one measurement electrode, through the central opening; and
comprising at least one electrical winding, supplied by an alternating electrical signal (V), arranged to generate a circular magnetic field (B) in the excitation toroidal element and an axial magnetic field vector potential (E) in said central opening;
so as to induce, in said electrical conductor, an alternating potential difference equal to said working alternating electrical potential (V_{g}), between an input and an output of said at least one toroidal element.

2. The device according to claim 1, characterized in that the polarization module comprises several toroidal elements, each comprising at least one electrical winding supplied by an alternating voltage (V), so as to induce an alternating potential difference equal to the working alternating electrical potential (V_{g}) in any conductor passing through all of said toroidal elements.

3. The device according to claim 1, characterized in that at least one excitation toroidal element comprises a ferromagnetic core around which is wound the at least one electrical winding of said excitation toroidal element.

4. The device according to claim 1, characterized in that at least one excitation toroidal element comprises several distinct electrical windings.

5. The device according to claim 1, characterized in that the polarization module comprises, for at least one electrical winding of an excitation toroidal element, an electric power supply circuit for said winding forming, with said electrical winding, a resonant circuit tuned to the working frequency.

6. The device according to claim 1, characterized in that it comprises an induction sensor, connected to the measurement electronics, and configured to provide said measurement electronics with an electrical signal as a function of the electrode-object capacitance seen by at least one measurement electrode, said induction sensor comprising at least one toroidal element, called receiving toroidal element, comprising a central opening:
provided to be placed around an electrical conductor electrically connected to said at least one measurement electrode; and
comprising at least one electrical winding, called receiving electrical winding, in which said electrical signal is induced.

7. The device according to claim 6, characterized in that the measurement electronics comprise a voltage amplifier, respectively a transimpedance amplifier, connected to said induction sensor and outputting a voltage (Vₛ) relative to the voltage, respectively to the current, provided by said induction sensor, and in particular by the electrical winding of said induction sensor.

8. The device according to claim 1, characterized in that the measurement electronics comprise an amplifier of the transimpedance type configured to measure a current or a charge originating from at least one measurement electrode and output a voltage (Vₛ) as a function of said current, respectively of said charge.

9. An appliance including:
a capacitive detection device according to claim 1; and
at least one measurement electrode electrically connected to an electrical conductor passing through the central opening of the at least one excitation toroidal element of the polarization module of said capacitive detection device.

10. The appliance according to claim 9, characterized in that it comprises at least one measurement electrode comprising, or consisting of:
an additional capacitive electrode mounted on a portion of the appliance,
an electrically conductive part of said appliance, such as a casing or a trim element of said appliance,
a constituent portion of said appliance, such as a segment,
a functional head, in particular interchangeable, equipping said appliance, or
all of said appliance.

11. The appliance according to claim 9, characterized in that it comprises a polarization module positioned:
around a base element of said appliance serving to fix said appliance to an external support, or
between said base element and said external support, for example in the form of an intermediate part or a base, or
around one or a plurality of electrical cables connected to the appliance.

12. The appliance according to claim 9, characterized in that it comprises a first polarization module and a second polarization module positioned on either side of the at least one measurement electrode.

13. The appliance according to claim 12, characterized in that the second polarization module is arranged so as to induce, in at least one electrical conductor passing through it, an alternating potential difference (−V_{g}) of the same value and opposite sign to the working alternating electrical potential (V_{g}), between an input of said second polarization module located on the side of the output of the first polarization module, and the output of said second polarization module.

14. The appliance according to claim 12, characterized in that the second polarization module is arranged so as to induce, in at least one electrical conductor passing through it, an alternating potential difference different from said working alternating electrical potential (V_{g}), between an input of said second polarization module located on the side of the output of the first polarization module, and the output of said second polarization module.

15. The appliance according to claim 9, characterized in that the capacitive detection device comprises at least one induction sensor placed:
around one or a plurality of electrical conductors electrically connected to at least one measurement electrode,
around a base element of said appliance serving to fix said appliance to an external support,
between said base element and said external support, for example in the form of an intermediate part or a base, or
around one or a plurality of electrical cables connected to said appliance.

16. The appliance according to claim 9, characterized in that the appliance is a robot or a portion of a robot, mobile or fixed.

17. The appliance according to claim 9, characterized in that the appliance is a display device comprising an electrical display screen.
